(19) United States
(12) Patent Application Publication
(10) Pub. No.: US 2021/0348001 A1
(43) Pub. Date: Nov. 11, 2021

(54) COATING MATERIAL, CONVERSION MATERIAL, OPTOELECTRONIC COMPONENT AND METHOD FOR PRODUCING A COATING MATERIAL

(71) Applicant: OSRAM Opto Semiconductors GmbH, Regensburg (DE)

(72) Inventor: Vesna MÜLLER, Vaterstetten (DE)

(21) Appl. No.: 17/278,556

(22) PCT Filed: Oct. 1, 2019
(86) PCT No.: PCT/EP2019/076631

§ 371 Date: Mar. 22, 2021

(30) Foreign Application Priority Data
Oct. 11, 2018 (DE) 10 2018 125 183.1

(51) Int. Cl. C09D 5/22; C09D 5/02; C09D 7/61; C09D 7/63; C09D 7/40; C09D 183/04; H01L 33/50

(52) U.S. Cl. CPC C09D 5/22; C09D 5/024; C09D 7/61; C08K 5/057; C09D 7/67; C09D 183/04; H01L 33/502; C09D 7/63

(57) ABSTRACT

An enveloping material for an optoelectronic semiconductor chip is specified having —a starting material for forming a sol-gel material, and —a stabilizer material, configured for mechanical stabilization, wherein —the starting material comprises at least one alkoxy (alkyl)silane, and —the stabilizer material is selected from a group containing the following materials: salts, metal alkoxides, metal oxides. Furthermore, a conversion material and an optoelectronic component having such an enveloping material are specified. Additionally, a method for producing an enveloping material is specified.

A coating material, a conversion material, and an optoelectronic component are specified. Furthermore, a method for producing a coating material is specified.

A coating material is specified. For example, the coating material is provided as a coating material for an optoelectronic semiconductor chip. This means, the coating material is provided for coating an optoelectronic semiconductor chip and thus protecting it from external mechanical or chemical influences. Alternatively or additionally, the coating material may serve as a matrix material for a phosphor material to form a conversion material. The coating material is preferably permeable or transparent to electromagnetic radiation, in particular visible light. For example, the electromagnetic radiation may be emitted or detected by the optoelectronic semiconductor chip during its operation.

According to at least one embodiment, the coating material for an optoelectronic semiconductor chip comprises a starting material for forming a sol-gel material.

The starting material may be inserted to a solvent during a production of the coating material. There, the starting material is preferably partially hydrolyzed and converted to a hydrolyzed compound. A sol refers to the partially polymerized starting material that is free in the solvent. In the solvent, the starting material partially polymerizes to form a 3D structure called gel, which comprises solvent molecules embedded in the 3D structure. That is, the sol-gel material is not polymerized over its entire volume, but forms a liquid of—compared to the gel—low viscosity. For example, the starting material can also be polymerized into a gel without solvent.

For example, the sol-gel material can be destabilized to the coating material by at least partial removal of the solvent, such as annealing processes at elevated temperatures, to form a solid body of coating material.

Preferably, the sol-gel material is configured to adhere to an optoelectronic semiconductor chip. That is, the sol-gel material may be formed such that after coating as well as removal of the solvent, the coating material adheres to the optoelectronic semiconductor chip. The coating material then resists detachment—for example by means of mechanical force—at least within certain limits. This means, for example, that during further processing of the optoelectronic semiconductor chip coated with the coating material, the layer does not come off.

According to at least one embodiment, the coating material comprises a stabilizer material. The stabilizer material is configured to mechanically stabilize the coating material. Preferably, the stabilizer material is embedded in the sol-gel material. It has been found that without the addition of stabilizer material, the polymerization to the sol-gel material can proceed in an uncontrolled manner, resulting in a shortened shelf life of the coating material. In addition, comparative coating materials without stabilizer material comprise a shorter polymerization time in the production, which also leads to an undesirably fast and/or uncontrolled polymerization.

According to at least one embodiment, the coating material comprises as starting material a material comprising or being an alkoxy(alkyl)silane. The alkoxy(alkyl)silane is referred to as an alkoxyalkylsilane, on the one hand, and an alkoxysilane, on the other hand. The alkoxy(alkyl)silane refers to a group comprising a silicon atom having four organic substituents. Preferably, the substituents are alkyl groups and/or alkoxy groups.

According to at least one embodiment, the stabilizer material is selected from a group comprising salts, metal alkoxides and/or metal oxides. In this regard, the stabilizer material may comprise salts, metal alkoxides and/or metal oxides. Further, the stabilizer material may comprise salts, metal alkoxides, or metal oxides that are nanoparticles.

Salts are chemical compounds of negatively charged ions, anions, and positively charged ions, cations. Preferably, the chemical bond between cations and anions is an ionic bond. Preferably, the salts can dissociate into their corresponding cations and anions in the liquid medium, here in the solvent. Similarly, the metal alkoxides and metal oxides can dissociate in the liquid medium.

The nanoparticles indicate assemblies of a few to a few thousand atoms or molecules. The diameter of the nanoparticles—for example, the mean diameter d50—is, for example, between at least 1 nm and at most 2000 nm, in particular at most 500 nm.

According to at least one embodiment, the coating material comprises a starting material for forming a sol-gel material and a stabilizer material configured for mechanical stabilization. The starting material comprises at least one alkoxy(alkyl)silane and the stabilizer material is selected from a group comprising salts, metal alkoxides and/or metal oxides as materials.

According to at least one embodiment, the coating material consists of a starting material for forming a sol-gel material and a stabilizer material configured for mechanical stabilization.

According to at least one embodiment, an oxygen atom of the sol-gel material coordinates to the metal ion of the stabilizer material. A coordinating bond is a weak bond in which the bonding electron pair capable of bonding originates from the oxygen atom of the sol-gel material. The stabilizer material is selected from the group consisting of salts, metal alkoxides and/or metal oxides which are dissociated and/or hydrolyzed in a liquid medium as ions. An oxygen atom of the sol-gel material coordinates to the positively charged ions of the stabilizer material.

According to at least one embodiment, the stabilizer material is selected from a group comprising phosphate salts, halide salts, carbonates, nitrates, sulfates, and combinations thereof. Preferably, any salt that comprises water solubility and that can be coordinated by the oxygen atom of the sol-gel material can be used as the stabilizer material. Preferably, ammonium phosphate, sodium phosphate, sodium hydrogen phosphate, sodium dihydrogen phosphate are used as the phosphate salt. As halide salts, for example, sodium chloride, calcium chloride and aluminum chloride are used. In the case of carbonates, sodium carbonate is preferably used. Particularly preferably, at least one salt is inserted as stabilizer material. It is also possible that two or more different salts are brought in as stabilizer material and/or that at least one of the salts is in the form of nanoparticles.

Salts of different valence can be used as stabilizer material. The valence of an ion indicates how many atoms it can bind to itself in a chemical bond. Monovalent, divalent, trivalent and tetravalent ions are the preferred stabilizer materials.

The proportion of salts as stabilizer material in the coating material depends on the specific salt used. For example, the proportion of aluminum chloride as stabilizer material in the coating material is between at least 0.1 wt % and at most 50 wt %. The proportion of sodium chloride as stabilizer material in the coating material is preferably significantly lower and is in the coating material at least 0.01 wt % and at most 5 wt %. If the salt content in the coating material is too high, the adhesion of the coating material, for example to the optoelectronic component, may be negatively affected.

The advantage of insertion the salt as stabilizer material into the coating material is the coordination of the oxygen atom of the sol to the cations of the salt. This leads to a slower polymerization due to the coordination of the sol to the cations of the salt, which leads to a lower mobility of the sol. Thus, rapid, uncontrolled polymerization to the gel can be minimized with advantage. The insertion of different salts resulting in different coordination properties leads to different durability of the coating material. The durability of the coating material is preferably determined by the choice of the appropriate salt.

According to at least one embodiment, the stabilizer material is selected from a group of metal alkoxides. In particular, any metal alkoxide that comprises water solubility and that can be coordinated by the oxygen atom of the sol-gel material can be used as the stabilizer material. The metal alkoxides are selected from a group of monovalent, divalent, trivalent and tetravalent materials. Metal alkoxides comprise the general formula M(OR)_{N}. M can be selected from the following metals: Alkali metals, alkaline earth metals, from the metals of the boron group and subgroups. R preferably denotes alkyl substituents such as methyl, ethyl, propyl, isopropyl, butyl, Tert-butyl substituents. n is a natural number which depends on the metal and is in particular between 1 and 4. Preferred materials are: metal ethoxides, metal methoxides, metal isopropoxides and metal butoxides. For example, titanium (IV) isopropoxide, titanium (IV) butoxide, titanium (IV) ethoxide, aluminum isopropoxide, zirconium (IV) ethoxides and zirconium (IV) isopropoxides can be used as stabilizer materials.

According to at least one embodiment, the coating material comprises metal oxides as stabilizer material. Metal oxides that can be coordinated by the oxygen atom in the sol-gel material are used as the stabilizer material. The metal oxides are selected from a group of monovalent, divalent, trivalent and tetravalent materials. Particularly preferably, the metal oxides are selected from a group including titanium dioxide, zirconium (IV) oxide, and aluminum oxide.

Preferably, the metal oxide is in the form of a nanomaterial. For example, a refractive index of the coating material can be increased by the addition of the nanomaterial as a stabilizer material. In particular, suitable nanomaterials can be nanoparticles, nanorods, nanowires or nanosheets. These may be formed from TiO₂, ZrO₂, BaTiO₃, SrTiO₃, TCO (Transparent Conductive Oxides), Al₂O₃, Nb₂O₅, HfO₂, ZnO, and the like. Metal oxides can help stabilize the coating material and lower the processing temperature.

TCOs are transparent conductive oxides. In particular, the TCOs comprise doped In₂O₃, SnO₂, ZnO, or CdO. Preferably, the oxides are doped with Sn, Zn, Al, Ga, or In. In particular, the oxides are doped with at least 1 mol % to at most 40 mol % such as In₂O₃ doped with 3 mol % Sn or In₂O₃ doped with 10 mol % Sn. Other examples of TCO include ITO (indium tin oxide), ATO (antimony doped tin oxide), IZO (indium zinc oxide), AZO (antimony doped zinc oxide), IMO (indium doped molybdenum oxide), IGO (indium doped gallium oxide), and mixtures thereof. Examples of nanoparticles that can be used to increase the refractive index include TiO₂, ZrO₂, BaTiO₃, ITO (indium tin oxide), TCO, Al₂O₃, Nb₂O₅, TiO₂, ZrO₂, BaTiO₃, SrTiO₃, Al₂O₃, Nb₂O₅, HfO₂, ZnO, and the like.

Preferably, the diameter of the nanoparticles comprises between at least 1 nm and at most 2 μm—for example, the average diameter d50—between at least 1 nm and at most 20 nm. The insertion of nanoparticles into the sol-gel material as a stabilizer material affects the refractive index of the coating material and/or the stabilization and durability of the coating material. Preferably, the nanoparticles comprise a larger refractive index than the coating material without nanoparticles or conventional silicones, respectively.

Preferably, the amount of nanoparticles inserted into the sol-gel material depends on the refractive index of the nanoparticles and/or the stabilization capabilities of the nanoparticles on the coating material. The larger the refractive index of the nanoparticles, the smaller the amount of nanoparticles to be inserted into the sol-gel material. For example, for nanoparticles with a small refractive index, a larger proportion of nanoparticles is required and inserted in the coating material than for nanoparticles with a larger refractive index, if a certain predeterminable refractive index is to be set. Particularly preferably, it is also possible that two or more different types of nanoparticles are inserted as stabilizer material. In addition, a combination of metal oxides and salts, or metal oxides and metal alkoxides, metal alkoxides and salts, or metal oxides and salts and metal alkoxides can be inserted as stabilizer material to better adjust the desired material properties.

According to at least one embodiment of the coating material, a surface of the stabilizer material is free of a modification. The modification describes the bringing in of, for example, organic groups which are bonded to the surface of the stabilizer material. Hydroxy groups may be used as organic groups.

According to at least one embodiment, the coating material comprises an alkoxy(alkyl)silane, as starting material, of a structural unit A of the following general formula:

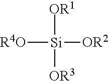

wherein the substituents R¹ to R⁴ are each independently selected from the group consisting of alkyls. The alkyl substituents preferably comprise a hydrocarbon residue C₁-C₄. Particularly preferably, the alkyl substituents are selected from the group consisting of:
methyl,
ethyl
propyl
isopropyl
butyl,
tert-butyl.

For example, the coating material comprises tetraethyl orthosilicate (TEOS) and/or tetramethyl orthosilicate (TMOS) as starting material. In particular, combinations of different alkoxy(alkyl)silanes of structural unit A are used as coating material.

According to at least one embodiment, the coating material comprises an alkoxy(alkyl)silane, as starting material, of a structural unit B of the following general formula:

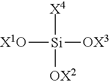

wherein the substituents X¹ to X⁴ are each independently selected from the group consisting of alkyls. The alkyl substituents preferably comprise a hydrocarbon residue C₁-C₄. Particularly preferably, the alkyl substituents are selected from the group consisting of:
methyl,
ethyl
propyl
isopropyl
butyl,
tert-butyl.

For example, the coating material comprises as starting material trimethoxymethylsilane, triethoxymethylsilane, trimethoxyethylsilane, ethyltriethoxysilane, ethyltriisopropoxysilane and combinations thereof.

According to another exemplary embodiment, the coating material comprises a starting material comprising, in addition to the structural unit A, another structural unit B different from the structural unit A. Preferably, the coating material comprises or consists of tetraethyl orthosilicate (TEOS) and/or tetramethyl orthosilicate (TMOS) in combination with trimethoxymethylsilane and/or triethoxymethylsilane and/or further alkoxy(alkyl)silanes as starting material. The proportion of alkoxy(alkyl)silanes of structural unit B, for example trimethoxymethylsilanes (MTMOS) and triethoxymethylsilanes (MTEOS), in the coating material is between at least 0 wt % and at most 100 wt %. Here, the proportion of the alkoxy(alkyl)silanes of the structural unit A is preferably between at most 100 wt % and at least 0 wt %.

The addition of the alkoxy(alkyl)silane of the structural unit B, preferably MTMOS and/or MTEOS, to the sol-gel synthesis of structural unit A with stabilizer material leads to a stabilization of the 3D structure of the sol-gel material. In particular, the addition of the alkoxy(alkyl)silane of structural unit B, preferably MTMOS and/or MTEOS, to the sol-gel synthesis with stabilizer material leads to less cracking, which can be caused during curing to the coating material, for example by an annealing process, compared to pure silicate materials based on alkoxy(alkyl)silanes of structural unit A, preferably tetraethyl orthosilicate and/or tetramethyl orthosilicate. Alkoxy(alkyl)silanes of structural unit B, preferably MTEOS- and/or MTMOS-based sol-gel materials, preferably form a polysiloxane comprising an alkyl group X⁴, preferably methyl group, on the silicon atom. The alkyl group on the silicon atoms alters the 3D structure of the gel such that crack-resistant films are formed when cured to the coating material. That is, alkoxy(alkyl)silanes of structural unit B, preferably MTEOS- and/or MTMOS-based sol-gel material with stabilizer material, preferentially result in a coating material that is less susceptible to cracking.

Preferably, the alkoxy(alkyl)silane of structural unit B, especially preferably MTEOS- and/or MTMOS-based sol-gel material with stabilizer material, comprises a better adhesion of the coating material, on for example the optoelectronic semiconductor chip, compared to a sol-gel material based on alkoxy(alkyl)silanes of structural unit A, preferably tetraethyl orthosilicate and/or tetramethyl orthosilicate. One reason for the improved adhesion of the coating material is the reduced cracking in the coating material.

A conversion material is further specified. The conversion material is provided, for example, for converting a primary electromagnetic radiation of a first wavelength range into secondary electromagnetic radiation of a second wavelength range. For this purpose, phosphor material responsible for the conversion of electromagnetic radiation is embedded, for example, in a coating material serving as a matrix material.

The conversion material may in particular be formed as a conversion layer.

According to at least one embodiment, the conversion material comprises a coating material described herein. That is, all features disclosed for the coating material are also disclosed for the conversion material and vice versa.

According to at least one embodiment, the conversion material comprises a phosphor material. The phosphor material is preferably formed as phosphor particles and is embedded in the coating material. Particularly preferably, the phosphor particles comprise a ceramic host lattice, an organic conversion material or quantum dots. Preferably, the phosphor particles comprise a garnet phosphor. Particularly preferably, the garnet phosphor is a YAG phosphor with the chemical formula Y₃Al₅O₁₂:Ce³⁺. The garnet phosphor preferably converts primary electromagnetic radiation of a first wavelength range to secondary electromagnetic radiation of a second wavelength range. The second wavelength range is preferably in the green and/or yellow wavelength range.

An optoelectronic component is further specified. The optoelectronic component is provided, for example, for generating and subsequently emitting a primary electromagnetic radiation of a first wavelength range in a semiconductor chip. The emitted primary electromagnetic radiation is converted into secondary electromagnetic radiation in a conversion material comprising a phosphor material and a coating material described herein.

According to at least one embodiment, the optoelectronic component comprises a conversion material described herein.

That is, all features disclosed for the conversion material are also disclosed for the optoelectronic component, and vice versa.

According to at least one embodiment, the optoelectronic component comprises a semiconductor chip that emits primary electromagnetic radiation of a first wavelength range during operation. The semiconductor chip is, for example, a light emitting diode chip or a laser diode chip. In operation, the semiconductor chip may emit electromagnetic primary radiation from the wavelength range of UV radiation and/or blue light, for example.

According to at least one embodiment, the optoelectronic component comprises a conversion material described herein that is configured to emit secondary radiation of a second wavelength range that is different from the first wavelength range. The conversion material is preferably arranged downstream of the semiconductor chip. The conversion material is configured to generate a partial conversion or a full conversion. This depends in particular on the phosphor material used and the thickness of the conversion material. “Downstream” means that at least 50% percent, in particular at least 85%, of the radiation emitted by the semiconductor chip enters the conversion material.

A higher refractive index in the coating material of the conversion material, preferably achieved by adding metal oxides, for example nanoparticles as stabilizer material in the coating material, improves with advantage the light extraction of the optoelectronic semiconductor chip through the conversion material.

A method for producing a coating material is further specified. Preferably, the method described herein can be used to produce the coating material described herein. That is, all features disclosed for the coating material are also disclosed for the method for producing a coating material, and vice versa.

According to at least one embodiment of the method for producing a coating material, a solvent is provided. The solvent comprises a pH of at most 5.

According to at least one embodiment of the method, a starting material is inserted into the solvent to form a sol-gel material.

According to at least one embodiment, a stabilizer material configured for mechanical stabilization is inserted into the coating material into the solvent or directly into the starting material. For example, the stabilizer material is inserted into the solvent with the starting material. Here, the stabilizer material is embedded in the sol-gel material.

According to at least one embodiment, the starting material is selected from the group of alkoxy(alkyl)silanes. The stabilizer material is selected from a group comprising salts, metal alkoxides and/or metal oxides as materials.

According to at least one embodiment of the method for producing a coating material, a solvent having a pH of at most 5 is provided. In a further step, the starting material is inserted into the solvent to form the sol-gel material. The stabilizer material configured for mechanical stabilization is inserted into the solvent. The starting material is selected from the group consisting of alkoxy(alkyl)silanes and the stabilizer material is selected from the group consisting of salts, metal alkoxides and/or metal oxides as materials.

According to at least one embodiment of the method, the solvent is selected from a group of protic solvents. Protic solvents have a functional group from which hydrogen atoms can be split off as protons and the starting material can thereby be hydrolyzed. For example, water and alcohols and combinations thereof are used as solvents. Preferably, the alcohol comprises methanol, ethanol, isopropanol and butanol.

According to at least one embodiment of the method, the pH of the solvent is at most 5. The pH is adjusted using an acid, in particular hydrochloric acid, formic acid or acetic acid. A low pH is advantageous, since the starting material can then be hydrolyzed particularly quickly.

The starting material is hydrolyzed by the solvent. The resulting hydrolyzed compound reacts with another hydrolyzed compound and/or the alkoxy(alkyl)silane to form a dimer. Subsequent polycondensation reactions polymerize the dimer to form a polymer. The polymers in which solvent is embedded are called gels.

The proportion of solvent and the proportion of acid in the solvent affect the rate of formation of the gel. If the polymerization time is short, processability of the coating material is limited. Preferably, a low proportion of acid is selected that results in controlled polymerization.

According to at least one embodiment of the method, the stabilizer material is inserted into the solvent before the starting material is inserted. In this context, it has proved particularly advantageous to insert the stabilizer material into the solvent before the starting material. At a later stage, the starting material may already have polymerized to a certain extent to form the sol-gel material, and the coordination from the oxygen atoms of the starting material to the stabilizer material is more difficult. That is, a small portion of the stabilizer material may be embedded in the 3D structure of the gel.

According to at least one embodiment, the insertion of the starting material and the insertion of the stabilizer material are performed under continuous mechanical mixing. Due to the continuous mechanical mixing, the stabilizer material can be well homogenized with the starting material and the stabilizer material can be embedded into the 3D structure of the gel, homogeneously distributed.

One idea of the present coating material is to insert a stabilizer material into a sol-gel material, so that the adhesion of the coating material to an optoelectronic semiconductor chip can be improved and the durability of the coating material can be improved compared to comparative sol-gel materials without stabilizer materials.

Furthermore, inserting metal oxides, in particular nanoparticles as stabilizer material into the sol-gel material leads inter alia to a specific adjustment of the refractive index of the coating material. A higher refractive index improves the light extraction of the optoelectronic semiconductor chip.

The insertion of additional alkoxy(alkyl)silanes, preferably of structural unit B, into the sol-gel material reduces cracking of the coating material, which leads to improved adhesion of the coating material to the optoelectronic semiconductor chip.

Additionally, an undesirable yellowing of the coating material due to UV radiation is prevented or at least inhibited by inserting stabilizer material into the coating material.

Further advantageous embodiments and further embodiments of the coating material, conversion material and optoelectronic component and of the method for producing a coating material are apparent from the exemplary embodiments described below in conjunction with the figures.

It show:

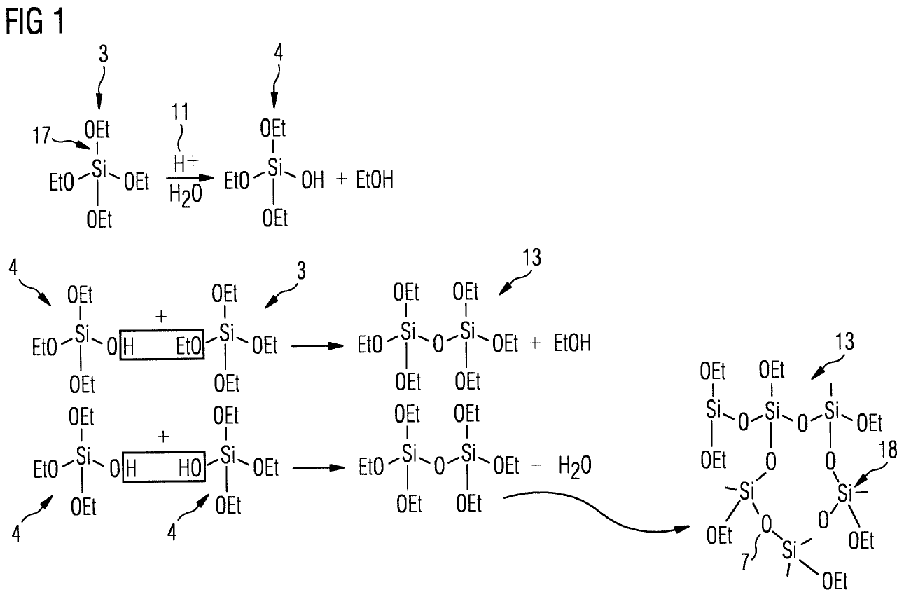

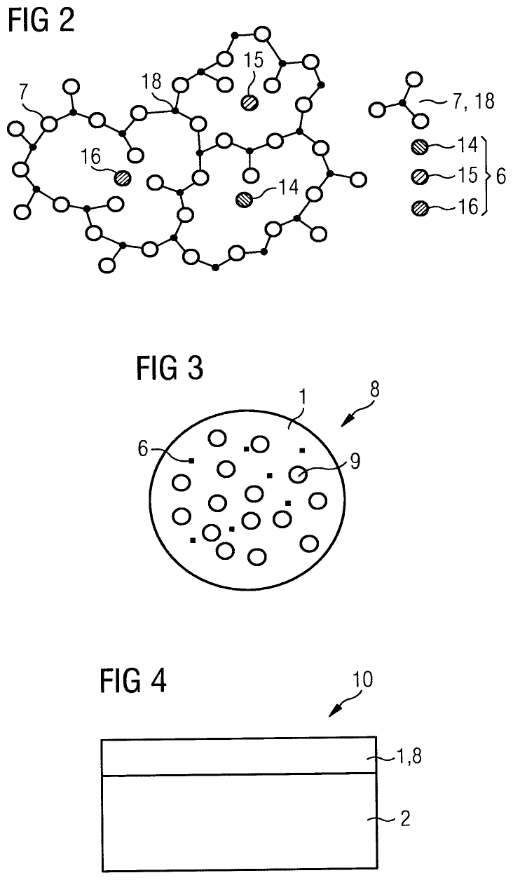

FIGS. 1 and 2 each a chemical representation of a coating material according to a respective exemplary embodiment,

FIG. 3 schematic sectional view of a conversion material according to an exemplary embodiment,

FIG. 4 schematic sectional view of an optoelectronic component according to an exemplary embodiment,

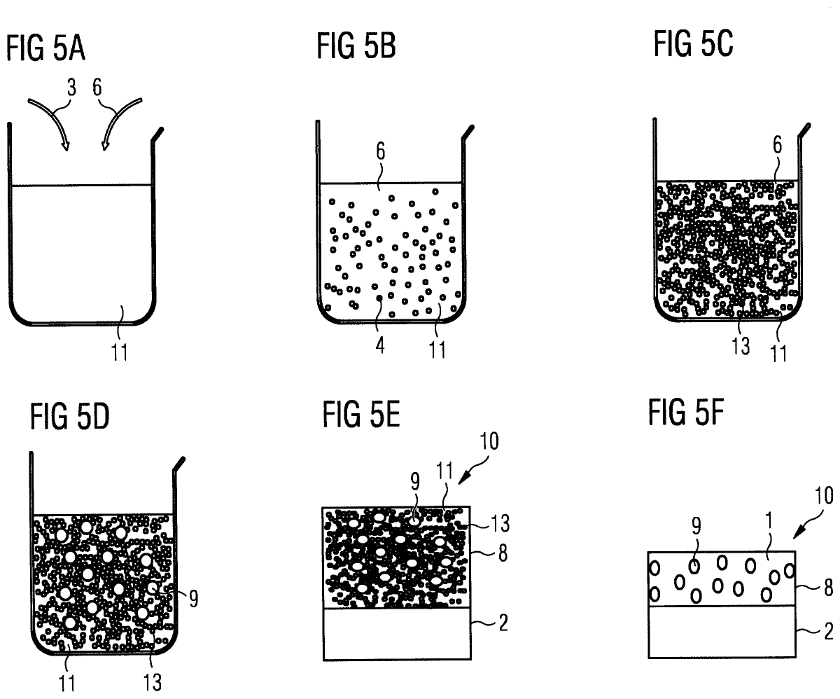

FIGS. 5A, 5B, 5C, 5D, 5E and 5F schematic sectional views of various stages of a method for producing a coating material and applying a conversion material to an optoelectronic semiconductor chip according to an exemplary embodiment,

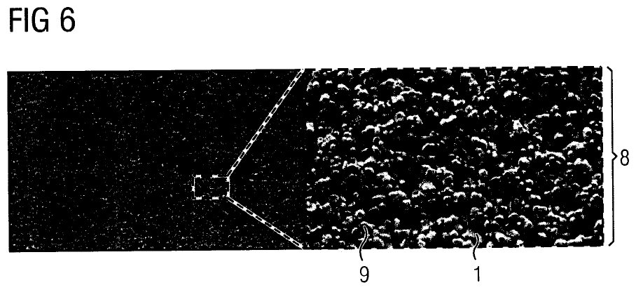

FIG. 6 scanning electron microscope image of a conversion material according to an exemplary embodiment.

Identical elements, elements of the same kind or elements having the same effect are given the same reference signs in the figures. The figures and the proportions of the elements shown in the figures with respect to one another are not to be regarded as to scale. Rather, individual elements, in particular layer thicknesses, may be shown exaggeratedly large for better representability and/or understanding.

The coating material 1 according to the exemplary embodiment of FIG. 1 comprises a starting material 3 for forming a sol-gel material 13. The starting material 3 used is an alkoxy(alkyl)silane, in this case tetraethyl orthosilicate 17. The starting material 3 is first hydrolyzed by the protons of the solvent 11. Ethanol is split off to form a hydrolyzed compound 4. The hydrolyzed compound 4 reacts with the starting material 3, alkoxy(alkyl)silane to form a dimer and ethanol. Similarly, a dimer can be formed by reacting two hydrolyzed compounds 4. In this case, water is formed as the second product instead of ethanol. Tetramers, oligomers and polymers can be formed from at least two dimers by an inorganic polycondensation reaction. In addition, tetramers, oligomers and polymers can be obtained from hydrolyzed compounds 4 and/or starting material 3, alkoxy(alkyl)silane. Silicon chains are formed, which are linked to each other via oxygen atoms 7. Part of the starting material is present polymerized as a gel in a 3D structure and another part is present as a sol which is free in the solvent.

The exemplary embodiment shown in FIG. 2 comprises a gel 5, in a 3D structure. Stabilizer material 6 is inserted into the gel 5. The stabilizer material 6 is configured for mechanical stabilization. The stabilizer material 6 can be formed as a metal oxide, metal alkoxide and as a salt. The stabilizer material 6 comprises, for example, monovalent cations 14, divalent cations 15 and/or trivalent cations 16. The stabilizer material 6 is formed as a cation and is coordinated by the oxygen atom 7 of the gel 5. The oxygen atom 7 is bonded by two silicon atoms 18 in each case. The insertion of the stabilizer material 6 into the gel 5 causes the ring tension in the 3D structure to be relaxed. That is, fewer cracks are formed in the gel 5.

The conversion material 8 according to the exemplary embodiment of FIG. 3 shows a coating material 1 described herein and a phosphor material 9. The phosphor material 9 is embedded in the coating material 1. The coating material 1 comprises a sol-gel material 13 in which stabilizer material 6 is inserted. The phosphor material 9 is formed as phosphor particles and comprises a ceramic host lattice, an organic conversion material 8, or quantum dots. The phosphor material 9 converts primary electromagnetic radiation of a first wavelength range into secondary electromagnetic radiation of a second wavelength range. For example, the phosphor material 9 comprises a garnet phosphor. The second wavelength range is, for example, in the green and/or yellow wavelength range. In particular, the garnet phosphor is a YAG phosphor having the chemical formula Y₃Al₅O₁₂:Ce³⁺.

The exemplary embodiment shown in FIG. 4 comprises an optoelectronic component 10. The optoelectronic component 10 comprises a semiconductor chip 2 which, in operation, emits primary electromagnetic radiation of a first wavelength range. The conversion material 8 converts electromagnetic primary radiation of a first wavelength range into electromagnetic secondary radiation of a second wavelength range. The conversion material 8 is arranged downstream of the optoelectronic semiconductor chip 2. For example, the conversion material 8 is arranged in direct contact to the optoelectronic semiconductor chip 2. Depending on the phosphor material 9, the conversion material 8 can completely convert the electromagnetic primary radiation of a first wavelength range into electromagnetic secondary radiation of a second wavelength range or partially convert parts of the electromagnetic primary radiation of a first wavelength range into electromagnetic secondary radiation of a second wavelength range.

In the method for producing a coating material 1 and subsequently applying it to an optoelectronic semiconductor chip 2 according to the exemplary embodiment of FIG. 5, a solvent 11, having a pH value of at most 5, is provided in a first step, FIG. 5A. First, the stabilizer material 6, which is provided for mechanically stabilizing the sol-gel material 13, is inserted into the solvent 11. The stabilizer material 6 is selected from a group comprising salts, metal alkoxides and/or metal oxides. Subsequently, a starting material 3 provided to form a sol-gel material 13 is inserted into the solvent 11. The stabilizer material 6 may comprise, for example, an aluminum salt or a sodium salt. This is stirred in the solvent 11 until it is completely dissolved. A starting material 3, for example TEOS, is then added to the solution. The reaction mixture is stirred for several hours, FIG. 5B. After a certain time under constant stirring, heat develops and the reaction mixture becomes transparent, for example, which is a consequence of the hydrolysis and polycondensation reaction to form the sol-gel material 13, FIGS. 5B, 5C.

As shown in FIG. 5C, the sol-gel material 13 with stabilizer material 6 is contained in a solvent 11. A portion of the sol-gel material 13 is polymerized to form the 3D structure of the gel 5 and another portion is present, for example, as a hydrolyzed compound 4, dimer, tetramer and/or oligomer.

As shown in FIG. 5D, the phosphor material 9 is placed in a vessel and the previously synthesized sol-gel material 13 is added to the phosphor material 9. The reaction mixture is continuously mechanically mixed to ensure homogeneous distribution of the phosphor material 9 in the sol-gel material 13.

In a next step, an optoelectronic semiconductor chip 2 is provided onto which the phosphor sol-gel material 13 is deposited, FIG. 5E.

In a final step, the solvent 11 is removed from the sol-gel material 13 to obtain a coating material 1, FIG. 5F. The removal of the solvent 11 is done by initial drying on air. Then, the optoelectronic semiconductor chip 2 with the applied phosphor sol-gel material is placed in an 80° C. and 300° C. oven for a period of time. The complete solvent 11 is removed and the formation of a conversion material 8 is obtained.

For the method for producing a coating material 1 and then depositing a conversion material 8 on an optoelectronic semiconductor chip 2 according to the exemplary embodiment of FIG. 5, two specific examples are specified below.

### EXAMPLE 1

Water, for example, is first provided as a solvent 11. The solvent 11 is adjusted to a pH value between 1 and 5, and an aluminum salt is added as a stabilizer material 6. The reaction mixture is mechanically mixed until the aluminum salt is dissolved. TEOS is added to the reaction mixture as the starting material and the reaction mixture is vigorously mechanically mixed for 0.5-3 hours. After about 0.5-2 hours of continuous mixing, heat develops in the reaction mixture and the reaction mixture becomes transparent, which is a result of the hydrolysis and polycondensation reaction starting to form the sol-gel material 13. Subsequently, mechanical mixing of the reaction mixture is stopped. Within in about one day, the sol-gel material 13 is further processed. A sol-gel material 13 with TEOS as the starting material 3 and without a stabilizer material 6 is further processed after a few hours compared to a sol-gel material 13 with a stabilizer material 6, because the polycondensation reaction to form a gel 5 is faster.

In a further step, for example, a YAG phosphor material 9 is placed in a glass vessel. The sol-gel material 13 with stabilizer material 6 is added. The reaction mixture is mechanically mixed until a homogeneous distribution of the phosphor material 9 in the sol-gel material 13 is achieved. Then, the sol-gel material 13 with stabilizer material 6 and phosphor material 9 is manually coated onto a microscopic glass slide or onto semiconductor chip wafer pieces. After coating the conversion material 8, the coated optoelectronic semiconductor chip 2 is dried in air and then placed in an oven. In the first annealing process, the coated optoelectronic semiconductor chip 2 is heated for a few minutes at an oven temperature between 70° C. and 100° C. and then cooled to room temperature in air. In the second annealing process, the coated optoelectronic semiconductor chip 2 is heated at an oven temperature of 300° C. and then cooled to room temperature in air.

### EXAMPLE 2

First, water is provided as a solvent 11. The solvent 11 is adjusted to a pH between 1 and 5, and a sodium salt is added as a stabilizer material 6. The reaction mixture is mechanically mixed until the sodium salt is dissolved. TEOS is added to the reaction mixture as the starting material and the reaction mixture is vigorously mechanically mixed for 45 minutes. Subsequently, the mechanical mixing of the reaction mixture is stopped. Within usually two weeks, the sol-gel material 13 is further processed. A sol-gel material 13 with TEOS as a starting material 3 and without a stabilizer material 6 is further processed after a few hours compared to a sol-gel material 13 with a stabilizer material 6, because the polycondensation reaction to form a gel 5 is faster.

In a further step, for example, a YAG phosphor material 9 is placed in a glass vessel. The sol-gel material 13 with stabilizer material 6 is added. The reaction mixture is mechanically mixed until a homogeneous distribution of the phosphor material 9 occurs in the sol-gel material 13. Then, the sol-gel material 13 with stabilizer material 6 and phosphor material 9 is manually coated onto a microscopic glass slide or onto semiconductor chip wafer pieces. After coating the conversion material 8, the coated optoelectronic semiconductor chip 2 is dried in air and then placed in an oven. In the first annealing process, the coated optoelectronic semiconductor chip 2 is heated at an oven temperature between 70° C. and 100° C. and then cooled to room temperature in air. In the second annealing process, the coated optoelectronic semiconductor chip 2 is heated at an oven temperature of 300° C. and then cooled to room temperature in air.

The insertion of sodium salt or aluminum salt as stabilizer material 6 into the sol-gel material 13 results in a slower gelation and thus t an improved adhesion of the conversion material 8 to the optoelectronic semiconductor chip 2. In addition, the cracking in the conversion material 8 is reduced compared to a conversion material 8 without stabilizer material 6.

The product of the method for producing a coating material 1 and subsequently applying it to an optoelectronic semiconductor chip 2, FIG. 5F, corresponds, for example, to the exemplary embodiment shown in FIG. 4. In both examples, an optoelectronic semiconductor chip 2 is shown which comprises the conversion material 8 downstream. The conversion material 8 comprises the phosphor material 9 and the described coating material 1.

FIG. 6 shows a scanning electron microscope image of the conversion material 8. The right image shows an enlarged image of the left image. Here, the coating material 1 comprises TEOS as alkoxy(alkyl)silane of structural unit A with the sodium salt as stabilizer material 6. Phosphor material 9 is inserted into the coating material 1. The phosphor material 9 is preferably formed as phosphor particles and is embedded in the coating material 1.

The invention is not limited to the exemplary embodiments by the description thereof. Rather, the invention encompasses any new feature as well as any combination of features, which in particular includes any combination of features in the patent claims, even if that feature or combination itself is not explicitly specified in the patent claims or exemplary embodiments.

This patent application claims priority of the German patent application DE 10 2018 125 183.1, the disclosure content of which is hereby incorporated by reference.

### LIST OF REFERENCE SIGNS

1 coating material
2 optoelectronic semiconductor chip
3 starting material
4 hydrolyzed compound
5 gel
6 stabilizer material
7 oxygen atom
8 conversion material
9 phosphor material
10 optoelectronic component
11 solvent
13 sol-gel material
14 monovalent cations
15 divalent cations
16 trivalent cations
17 tetraethyl orthosilicate
18 silicon atom

1. A coating material for an optoelectronic semiconductor chip comprising
a starting material for forming a sol-gel material, and
a stabilizer material configured for mechanical stabilization, wherein
the starting material comprises at least one alkoxysilane, and
the stabilizer material is selected from a group including the following materials: Salts, metal alkoxides, metal oxides,
in which an oxygen atom of the sol-gel material coordinates to the stabilizer material.

2. The coating material according to claim 1,
in which the stabilizer material is selected from a group comprising phosphate salts, halide salts, carbonates, nitrates, sulfates and combinations thereof.

3. The coating material according to claim 1
in which the stabilizer material is selected exclusively from the group of metal alkoxides.

4. The coating material according to claim 1,
in which the stabilizer material is selected from the group of metal oxides and is formed as nanoparticles.

5. The coating material according to claim 1,
in which a surface of the stabilizer material is free of a modification.

6. The coating material according to claim 1,
in which the alkoxysilane comprises a structural unit A of the following general formula: 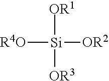
wherein the substituents R¹ to R⁴ are each independently selected from the group consisting of alkyls.

7. The coating material according to claim 1,
in which the alkoxy(alkyl)silane comprises a structural unit B of the following general formula: 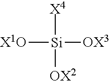
wherein substituents X¹ to X⁴ are each independently selected from the group consisting of alkyls.

8. The coating material according to claim 6,
in which the starting material comprises, in addition to the structural unit A, a further structural unit B different from the structural unit A.

9. A conversion material with
a coating material according to claim 1, and
a phosphor material, wherein
the phosphor material is embedded in the coating material.

10. An optoelectronic component comprising
a semiconductor chip which in operation emits electromagnetic primary radiation of a first wavelength range, and
a conversion material according to claim 9 configured to emit secondary radiation of a second wavelength range, wherein
the conversion material is arranged downstream of the semiconductor chip.

11. A method for producing a coating material comprising the steps:
providing a solvent having a pH of at most 5,
inserting a starting material to form a sol-gel material into the solvent,
inserting a stabilizer material configured for mechanical stabilization into the solvent, wherein
the starting material is selected from the group of alkoxysilanes, and
the stabilizer material is selected from a group containing the following materials: Salts, metal alkoxides, metal oxides.

12. The method according to claim 11,
wherein the solvent is selected from the group of protic solvents.

13. The method according to claim 11,
wherein the pH of the solvent is between 1 and most 5.

14. The method according to claim 11,
wherein the stabilizer material is inserted into the solvent or into the starting material prior to the insertion of the starting material.

15. The method according to claim 11,
wherein the insertion of the starting material and/or the insertion of the stabilizer material is carried out under continuous mechanical mixing.

16. The method according to claim 11,
in which a coating material according to claim 1 is produced.

17. A method for producing a coating material comprising the steps:
providing a solvent having a pH of at most 5,
inserting a starting material to form a sol-gel material into the solvent,
inserting a stabilizer material configured for mechanical stabilization into the solvent, wherein
the starting material is selected from the group of alkoxy(alkyl)silanes, and
the stabilizer material is selected from a group containing the following materials: Salts, metal alkoxides, metal oxides,
wherein an oxygen atom of the sol-gel material coordinates to the stabilizer material
